(19) United States
(12) Patent Application Publication
(10) Pub. No.: US 2024/0061978 A1
(43) Pub. Date: Feb. 22, 2024

(54) Methods And Systems For Use In Growth Stage Prediction

(71) Applicant: MONSANTO TECHNOLOGY LLC, Saint Louis, MO (US)

(72) Inventors: Michael Douglas DAILY, O'Fallon, MO (US); Xiaobo ZHOU, Chesterfield, MO (US)

(21) Appl. No.: 18/235,748

(22) Filed: Aug. 18, 2023

Related U.S. Application Data
(60) Provisional application No. 63/399,534, filed on Aug. 19, 2022.

(51) Int. Cl. G06F 30/27; G06Q 50/02

(52) U.S. Cl. CPC G06F 30/27; G06Q 50/02

(57) ABSTRACT

Systems and methods for predicting growth stages of crops in fields are provided. One example computer-implemented method includes accessing data associated with a target field and/or a crop in the target field and generating growth stage predictions, via multiple growth stage models, each associated with an interval of a growth period of the crop. The method also includes aggregating the growth stage predictions from the multiple growth stage models and outputting the aggregate growth stage prediction for the field. The method then further includes instructing operation of an agricultural machine relative to the target field and/or the crop in the target field, based on the aggregate growth stage prediction for the field, to treat and/or harvest the crop in the field.

### CROSS-REFERENCE TO RELATED APPLICATION

This application claims the benefit of, and priority to, U.S. Provisional Application No. 63/399,534, filed on Aug. 19, 2022. The entire disclosure of the above application is incorporated herein by reference.

### FIELD

The present disclosure generally relates to methods and systems for use in growth stage prediction of crops in fields, and in particular, to methods and systems for leveraging models of plant/crop growth stage, in combination, where each model is specific to a range of growth stage(s), to predict one or more growth stages of crops in fields.

### BACKGROUND

This section provides background information related to the present disclosure which is not necessarily prior art.

Crops are planted, grown, and harvested in various regions. After planting the crops, depending on types of the crops, the crops progress through various growth stages until harvest. The growth stages may be determined, for example, through physical examination or inspection of the crops. In doing so, the physical examination or inspection may include various measurements or other inspections of the crops that additionally define a need for one or more treatments to be applied to the crops at one or more of the determined growth stages, in order to enable desired performance of the crops (e.g., based on yield, etc.). Further, growth stages of crops may be estimated by analyzing images of fields in which the crops are located, as captured by satellites or unmanned aerial vehicles (UAVs), whereby the crops in the fields are indicated as being at specific growth stages at the time of the images.

### SUMMARY

This section provides a general summary of the disclosure and is not a comprehensive disclosure of its full scope or all of its features.

Example embodiments of the present disclosure generally relate to methods for predicting one or more growth stages of a crop in a field. In one example embodiment, such a method generally includes: accessing, by a computing device, data associated with a target field and/or a crop in the target field; generating, by the computing device, growth stage predictions, via multiple growth stage models, each associated with an interval of a growth period of the crop; aggregating, by the computing device, the growth stage predictions from the multiple growth stage models; and outputting, by the computing device, the aggregate growth stage prediction for the field. In some implementations, the method also includes instructing, by the computing device, operation of an agricultural machine relative to the target field and/or the crop in the target field based on the aggregate growth stage prediction for the field.

Example embodiments of the present disclosure also generally relate to non-transitory computer-readable storage media including executable instructions for predicting growth stages of a crop in a field. In one example embodiment, a non-transitory computer-readable storage medium includes executable instructions, which when executed by at least one processor, cause the at least one processor to perform one or more of the steps recited in any of the methods herein.

Example embodiments of the present disclosure also generally relate to systems for predicting one or more growth stages of a crop in a field. In one example embodiment, such a system generally includes at least one computing device configured to: access data associated with a target field and/or a crop in the target field; generate growth stage predictions, via multiple growth stage models, each associated with an interval of a growth period of the crop; aggregate the growth stage predictions from the multiple growth stage models; output the aggregate growth stage prediction for the field; and generate instructions for an agricultural machine, based on the aggregate growth stage prediction for the field, to treat the crop in the field and/or to harvest the crop in the field, whereby the agricultural machine operates to treat and/or harvest the crop in the field in response to the instructions.

Further areas of applicability will become apparent from the description provided herein. The description and specific examples in this summary are intended for purposes of illustration only and are not intended to limit the scope of the present disclosure.

### DRAWINGS

The drawings described herein are for illustrative purposes only of selected embodiments, are not all possible implementations, and are not intended to limit the scope of the present disclosure.

FIG. 1 illustrates an example system of the present disclosure configured for predicting growth stages of crops in fields, through a combination of models;

FIG. 2 is a block diagram of an example computing device that may be used in the system of FIG. 1;

FIG. 3 illustrates a flow diagram of an example method, which may be used in (or implemented in) the system of FIG. 1, for use in predicting one or more growth stages associated with a crop, or multiple crops;

FIG. 4 illustrates an example flow diagram indicative of a maturity model for predicting growth stages of crops, for example, between emergence and growth stage R7, and which may be used in the system of FIG. 1 and/or the method of FIG. 3; and

FIGS. 5A-5C illustrates graphical representations of performance of different models in connection with implementation of the example prediction method of FIG. 3, as applied to soybean and corn crops in certain regions of North America (NA) and South America (SA).

Corresponding reference numerals indicate corresponding parts throughout the several views of the drawings.

### DETAILED DESCRIPTION

Example embodiments will now be described more fully with reference to the accompanying drawings. The description and specific examples included herein are intended for purposes of illustration only and are not intended to limit the scope of the present disclosure.

In assessing different crops, for different purposes, a specific growth stage of the crop may determine specific operations for the crop, including, for example, application of treatments, harvesting, imaging, etc. In doing so, the growth stage is typically determined, on site, in the field, for example, through examination and/or measurement of the crop (e.g., of plants associated with the crop, etc.), which may be time consuming, cumbersome and subjective to the technician/grower on site, etc. The growth stage may further be predicted, ahead of time, through a number of different techniques. Conventional prediction techniques may perform differently depending on the specific growth stage being predicted and/or crop being assessed, thereby potentially providing limited effectivity over the entire growth of the crops (e.g., from planting to harvest, etc.).

Uniquely, the systems and methods herein rely on a combination of different growth stage prediction models, for different growth stages, to predict the specific growth stage of a crop. In particular, a prediction computing device accesses data related to a field and then predicts the growth stage of a crop in the field, based on multiple different models, where each model is designated to a specific growth stage and/or range of growth stages. The prediction computing device further aggregates, combines, merges, etc. the model predictions, across the growth stages of the crop, to provide overall growth stage predictions for the crop. In this manner, the prediction computing device leverages the accuracy of the different growth stage models at different growth stages to provide accuracy across the entire growth of the crop (e.g., across all growth stages of the crop, etc.).

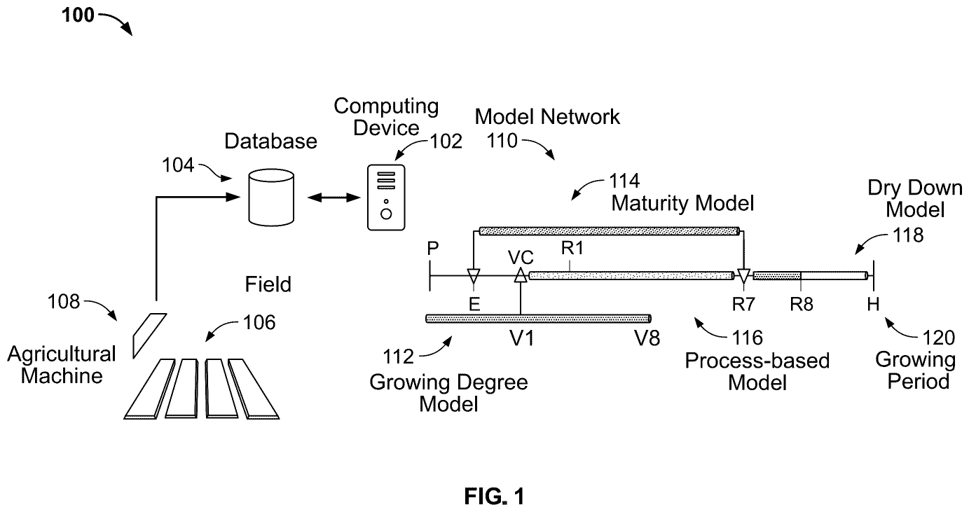

FIG. 1 illustrates an example system 100 in which one or more aspects of the present disclosure may be implemented. Although the system 100 is presented in one arrangement, other embodiments may include the parts of the system 100 (or additional parts) arranged otherwise depending on, for example, types of crops, associated models for growth stage prediction, sources of data (e.g., training data, etc.), types of data, arrangements of plots, geographic locations of plots, etc.

In the example embodiment of FIG. 1, the system 100 generally includes a prediction computing device 102 and a database 104. The database 104 is coupled to (and/or otherwise in communication with) the prediction computing device 102, as indicated by the arrowed line. The prediction computing device 102 is illustrated as separate from the database 104 in FIG. 1, but it should be appreciated that the database 104 may be included, in whole or in part, in the computing device 102 in other system embodiments.

The system 100 also includes an example field 106. The field 106, in general, is provided for planting, growing, and harvesting a crop or multiple crops, etc. The field 106 includes at least one crop planted therein (e.g., at least one plant associated with the at least one crop, etc.). The crop (and/or plant associated therewith) may include, for example (and without limitation), corn (or maize), wheat, beans (e.g., soybeans, etc.), peppers, tomatoes, tobacco, eggplant, rice, rye, sorghum, sunflower, potatoes, cotton, sweet potato, coffee, coconut, pineapple, citrus trees, prunes, cocoa, banana, avocado, fig, guava, mango, olive, papaya, cashew, almond, sugar beets, sugarcane, oats, barley, vegetables, or other suitable crop or products or combinations thereof, etc. In addition, plots of the field 106 may each include the same type of plants/crop, or a number of different varieties of the same type of plants (or crop), or different types and/or combinations of plants/crops.

The crop in this example may include soybeans. In connection with the crop being soybeans, generally, the example growth stages are presented below in Table 1 (and generally illustrated in FIG. 1).

TABLE 1

| Growth Stage | Description |
|---|---|
| P | Planting |
| E | Emergence |
| VC | Unifoliate leaves unrolled (Cotyledon) |
| V1-V8 | 1^{st} . . . 8^{th} trifoliate leaf unfolded |
| R1 | Beginning flowering |
| R2 | Full bloom |
| R3 | Beginning pod |
| R4 | Full pod |
| R5 | Beginning seed |
| R6 | Full seed |
| R7 | Beginning maturity |
| R8 | Full maturity |
| H | Harvest |

Alternatively, the crop may be, for example, corn, for which Table 2 includes, generally, example growth stages.

TABLE 2

| Growth Stage | Description |
|---|---|
| P | Planting |
| VE | Emergence |
| V1-V14 | 1^{st} . . . 14^{th} leaf visible |
| VT | Tasseling |
| R1 | Silk emergence |
| R2 | Blister |
| R3 | Milk |
| R4 | Dough |
| R5 | Dent |
| R6 | Physiological maturity |
| H | Harvest |

In addition, the system 100 may include an agricultural machine 108. In some examples the agricultural machine 108 may include, for example, a picker (e.g., a corn ear picker, etc.), a combine, etc., which is configured to harvest the crop from the field 106 and other fields. In other examples, the agricultural machine 108 additionally, or alternatively, includes a treatment machine (e.g., a sprayer, etc.), which is configured to apply one or more treatments to the field 106, or an irrigation machine (e.g., a pump, an irrigation pivot, a sprinkler, etc.), which is configured to apply irrigation to the field 106. In general, the agricultural machine 108 may include any machine associated with an operation at the field 106, which may be imposed based on a growth stage of the crop, etc. The agricultural machine 108 may further be configured to receive executable instructions from the computing device 102 and execute the instructions (e.g., via at least one processor of a computing device included in the agricultural machine 108 and/or in communication with the agricultural machine 108, etc.) at the field 106, to affect the crop therein. That said, while one agricultural machine 108 is illustrated in FIG. 1, it should be appreciated that the system 100 may include multiple such machines in other examples (e.g., multiple of the same type of agricultural machine, multiple different types of agricultural machines, etc.).

In addition to the above, the agricultural machine 108 may also include one or more measuring instruments associated with the field 106, which is/are configured to capture data related to the field 106 and to report the data to the database 104 (e.g., sensors, meters, thermometers, rain gauges, cameras, etc.). The database 104 in turn is configured to store the data, and to make the data available to the computing device 102. The data may include, for example, weather data (e.g., temperature, humidity, etc.), planting date, flowering date, field location and/or boundaries (e.g., by latitude, longitude, etc.), soil sample data, harvest date, and grain moisture (e.g., combined with harvest date to estimate R6 date, etc.), etc. Apart from the agricultural machine 108, it should be appreciated that certain data, such as, for example, weather data, may be captured by a third party and provided to the database 104, again, for use by the computing device 102 as generally described herein.

In this example embodiment, the computing device 102 is configured to access data included in the database 104, to access multiple models associated with the field 106 (e.g., by region, by growth stage, etc.), and to predict the growth stage of the crop in the field 106 based thereon.

In particular, the computing device 102 includes multiple different models, each associated with a different growth stage and/or range of growth stages for the crop in the field 106 (which may overlap, or not). In this embodiment, the crop is soybeans, and the computing device 102 includes a network 110 of models comprising a growing degree model 112, a maturity model 114, a process-based model 116, and a dry down model 118, each generally disposed along a growing period growth scale 120, which again, in this example, is for soybeans (i.e., from planting to harvest), at a growth stage range associated with the particular model. As such, each of the models (e.g., the network 110 of models, etc.) configures the computing device 102 to predict a growth stage of the crop in the field 106 for the associated growth stage range of the given model. That said, it should be appreciated that the network 110 of models may include more or less models in other embodiments, and/or may include one or more different models.

It should be appreciated that prior to predicting growth stage, the computing device 102 is configured to train the models, separately, based on data included in the database 104. For example, the database 104 may include data for crops in the field 106 and other fields (and data for the field(s)) over periods of years (e.g., year_1, year_2 . . . year_n, etc., where n is an integer). The training, in general, leverages the data included in the database 104, for prior years, as indicated above. The training data includes not only planting data, weather data, photoperiod data, etc., described herein, but also growth stage data for the crops indicative of the growth stage of the crops on specific days (e.g., relative to a planting date (P), etc. in general or for a given region including the field 106; etc.). In connection with training the models, the training data is separated into training data and validation data, whereby the validation data (e.g., for a particular year, for multiple particular years, etc.) is employed to validate the trained models.

That said, after training the models, in this example embodiment, and potentially also after validation of the models, the computing device 102 is configured to receive an instruction to generate growth stages for the crop in the field 106 (e.g., from a user, as part of a schedule, in response to a particular action taken with regard to the crop and/or the field 106, etc.). In response, the computing device 102 is configured to access data from the database 104, for the field 106, and in particular, data relevant to predicting growth stages. The data may include, for example, without limitation, planting data (e.g., planting dates for the crops in the field 106, etc.), weather data (e.g., temperature data, humidity data, etc. for the field 106 and/or for a region including the field 106; etc.), and other data specific to the field 106, the crop planted in the field 106, etc., as identified below. The computing device 102 is further configured to access the models of the network 110, and associated parameters, associated with the field 106 and/or the crop (e.g., soybeans, etc.) in the field 106. For example, the models may be specific to the crop in the field 106 (e.g., soybeans versus corn, etc.) and/or region including the field 106 (e.g., North America versus Latin America or South America, etc.). As indicated above, the models generally included in the network 110, in this example, are for soybeans and include the growing degree model 112, the maturity model 114, the process-based model 116, and the dry down model 118.

Next, the computing device 102 is configured to employ, implement, etc. each of the growing degree model 112, the maturity model 114, the process-based model 116, and the dry down model 118.

The growing degree model 112 is based, in this example, on temperature and relative maturity (RM). In this example embodiment, the growing degree model 112 is specific to the growth stages from planting (P) to V8 for soybeans, and also the growth stages R7 to R8 for soybeans.

In general, the growing degree model 112 is expressed in GDU or growing degree units, which, in this example, represents accumulated degree-days over 10° C. Specifically, for example, for the growth stages from planting (P) to emergence (E), the growing degree model 112 may include a GDU_PE model as the GDU accumulation target for the growth stages of planting to emergence, expressed herein by example Equation 1, in terms of temperature.

GDU_PE=max(122.4−3.53*meantemp_2wk_P,63.8) (1)

In Equation 1, meantemp_2wk_P is the mean temperature over a two-week period from 14 days before planting up to the planting date, in degrees Celsius (where all GDU, then, are in degrees Celsius). More generally, the target GDU is dependent on the mean temperature in the two weeks prior to planting of the crop, which is a proxy, in this example, for soil temperature. The computing device 102 is configured to generate the parameters of Equation 1, based on training data, as defined below.

Similarly, the growing degree model 112 is represented as GDU_i for growth stages VE to V8, which is the GDU accumulation target for the different growth stages, i (0 for VE, 1 for V8, etc.), as expressed by Equation 2. And, the growing degree model 112 is represented as GDU_R7-R8 for growth stages R7 to R8, which is the GDU accumulation target for these growth stages, as expressed by Equation 3.

GDU_i=52.90+48.58*I+10.64*RM_2.88*I*RM (2)

GDU_R7-R8=max(10,32.67+16.99*RM) (3)

As indicated above, in these examples (of Equations 2 and 3) the growing degree model 112 for these ranges of growth stages is based on RM, where higher RM is associated with more absorbed GDU than lower RM in crops. Again, as above, the computing device 102 is configured to generate the parameters of Equations 2 and 3 based on training data, as defined below. In particular, the computing device 102 is configured to leverage specific historical growth stage data (included in the database 104 and) collected by growers associated with various fields, through observation and/or measurement, etc., to train one or more linear regression models for GDU of the target stage versus relative maturity and the stage index (i.e., the GDU is converted to growth stage as the date on which the target GDU for the growth stage is accumulated). In view of the above, it should be appreciated that the particular values and/or terms are specific to a training data set, whereby the equations will vary depending on the data set (e.g., as defined by crop, timing, region (e.g., North America versus Latin America versus South America, etc.), etc.) and/or the crop reflected in the data set (e.g., corn versus soybeans, etc.).

The maturity model 114, in this embodiment, relies on location, weather and genetic features of the crop(s), where a machine learning model (e.g., a linear regression model, a Gaussian process regression model, etc.) is employed to predict the growth stage from emergence (E) to R7, consistent with a null stage and a weather-based stage (e.g., via a two-stage process, etc.).

In this example embodiment, in the null stage, the computing device 102 is configured to compile different null features of the crop(s), based on emergence day/date, planting date (e.g., for corn, etc.), set relative maturity (RM), latitude, longitude, elevation, irrigation, soil (e.g., cation exchange capacity, organic matter precent, pH, available water capacity, etc.), and/or combinations thereof. The combinations may include, for example, set_RM*emergence_day, set_RM*latitude, and emergence_day*latitude, where multiplication (as illustrated) is merely an example operation, and where other operations of such combinations of features may be included or used in lieu of the multiplication to define one or more null features. In general, then, the computing device 102 is configured to compile six null features of the crop(s) in this example embodiment (with it to be appreciated that the computing device 102 may compile a different number of null features in other embodiments). That said, it should be appreciated that the features noted above may be employed individually, or in combination, depending on the particular model, and capabilities and/or configurations thereof. For instance, a linear regression model may employ multiple features in combination (as indicated above), while a Gaussian process regression model may employ individual ones of the features.

Further, the computing device 102 is configured to compile the weather-based stage as weather features aggregated over two parts of the growth stage. The two parts may include emergence to a midpoint, for example, and then from the midpoint to roughly R7 (e.g., from the null stage prediction, etc.), where the weather features may include, without limitation, growing degree units (GDU), precipitation, diurnal temperature difference per day (or other interval) (i.e., Tₘₐₓ−Tₘᵢₙ), day length, solar radiation, vapor pressure deficit (VPD), and stress degrees (e.g., degree days over 30° C. or other temperature threshold, etc.), etc. The computing device 102, as part of the maturity model 114, then is configured to combine the weather features and the null features from the two stages. In some examples (e.g., in embodiments where the maturity model 114 includes a linear regression model, etc.), the computing device 102 is further configured to employ a backwards recursive elimination process, whereby the set of the null and weather features is reduced to an optimal set. Specifically, for example, if the null and weather features provide N features, the computing device 102 is configured to try feature elimination for each and to assess the impact of the individual feature elimination on performance of the model 114. The feature elimination which least impacts the performance of the model 114 is identified, and is then repeated until a limited set of the features is returned, which is within a threshold (e.g., 1%, 2%, 5%, or more or less, etc.), for example, of the root mean square error of the optimal model.

The computing device 102 is configured to train the maturity model 114 based on historical data included in the database 104. In one embodiment, a period of historical data is omitted from the historical data. The computing device 102 is then configured to validate the model based on the omitted data, and further, to tune the feature elimination and/or model 114 consistent with the omitted data.

The computing device 102 is configured to employ the process-based model 116, for growth stages between VC and R1 and then also between R1 and R7, for example. The process-based model 116, in this example, is based on temperature and day length. In connection therewith, a daily growth function (GR) may be used to predict the rate of development, according to Equation 4.

R_max=f(T)*f(P)*f(DP) (4)

In Equation 4, R_max is a maximum growth rate, f(T) is a temperature response (e.g., 0 to 1, etc.), f(P) is a photoperiod response (e.g., from 0 to 1, etc.), and f(DP) is a function of the difference in day length between the current and previous day, which is a penalty if the day length is increasing (e.g., before the summer solstice in North America, etc.). Based on the conditions in the filed 106, for example, the developmental growth phase may be expected to complete in 1/R_max days (e.g., for R_max=0.05, the development stage may be expected to complete in 20 days; etc.). Daily growth (GR), then, is accumulated (e.g., R_max is accumulated, etc.) until equal to 1, at which point the development phase is deemed complete.

In connection with the above, the equations below are also relevant. In particular f(T) is provided in Equation 5, below. Additionally, f(P) is provided in Equation 6 below, and f(DP) is provided in Equation 7 below.

$$f ( T ) = min ( \frac{G D U}{GDU\_max} , 1 ) \qquad ( 5 )$$

$$f ( P ) = \frac{1}{1 + {e}^{( {k}_{p} * {( P - {P}_{m i d} )}^{7}}} \qquad ( 6 )$$

$$f ( DP ) = \{ \begin{matrix}1 if DP > 0 \\ 1 - \frac{D P}{DP\_max} if DP > DP\_max \\ 0 if DP \geq DP\_max\end{matrix} \qquad ( 7 )$$

Table 3, below, provides example parameters that may be used in one embodiment of the process-based model 116. In this example, the following parameters are used for the process-based model 116: R_max, GDU max, P mid (e.g., day length at which the development rate is half-maximal and k_p is constant, etc.), k_p, and DP max (e.g., change in day length (hr) above which the development rate toward flowering is zero, etc.).

TABLE 3

| | Growth | RM | | GDHₘₐₓ | | | | |
|---|---|---|---|---|---|---|---|---|
| Region | Stage(s) | Range | Rₘₐₓ | (C) | P_{mid} | kₚ | DPₘₐₓ | B |
| NA | VC-R1 | [−2.0, 5.0) | 5.11E−02 | 6.41 | 0.111*RM\hat{ }2 − | 0.41 | 0.602 | 6 |
| | | | | | 0.431*RM + 18.05 | | | |
| | | [5.0, 9.0) | 5.03E−02 | 15.48 | 17.01-0.268*RM | 1.15 | 0.358 | |
| | R1−R7 | [−2.0, 5.0) | 2.37E−02 | 3.02 | 15.50-0.508*RM + | 1.01 | | 0.83 |
| | | | | | 0.0319*RM\hat{ }2 | | | |
| | | [5.0, 9.0) | 2.36E−02 | 0.57 | 14.80-0.215*RM | 1.55 | | |

It should be understood that the parameter B (which is an angle (e.g., in degrees, etc.) of the sun below the horizon at the beginning/end of a day) is included as a manner of determining a day length feature.

The values generated by the above, then, provide the growth stage, for example, from VC to R1 and then also from R1 to R7, as provided in Table 4 below.

TABLE 4

| Growth Stage | Fraction R1-R7 |
|---|---|
| R2 | 0.112 |
| R3 | 0.202 |
| R4 | 0.305 |
| R5 | 0.444 |
| R6 | 0.705 |
| R7 | 1 |

It should be appreciated that the parameters provided above are based on the computing device 102 being configured to train the process-based model 116 with certain historical data. As indicated in Table 3, at the left, the region is NA or North America. The training data corresponding to the above parameters, then, is North America historical data. Alternatively, other regions may be provided, whereby the computing device 102 is configured to train the process-based model 116 on relevant region-specific historical data.

It should be appreciated that the maturity model 114 and/or the process-based model 116 may be, optionally, omitted in favor of a further machine learning flowering model for the relevant growth stages. In one specific embodiment, for example, the computing device 102 may employ a regression model for growth stages VE to R1 and R1 to R7, where the regression model incorporates location, weather and genetic features, and is also consistent with the above. Consistent with the above, further, the training for the null and weather-based modeling may include a recursive elimination of features and estimates of the model error through a leave-one-year-out cross validation.

That said, the regression model (associated with the further machine learning flowering model) for the specific growth stages may include, for example, the trait predicted as the GDU from emergence to R1, which is then converted into predicted days for emergence E to R1. In some implementations, an indirect prediction of flowering date may be provided in this manner, rather than a prediction of flowering date directly. Also, the growth stage intervals for the weather-based model may be defined, for example, as the intervals E-M and M-R1, where E is emergence, R1 is the flowering date predicted by the null model, and M is the midpoint between the two dates. And, the growth stages R2-R6 may be predicted by the growing degrees between the predicted R1 and R7 dates using fractional progress (as compared to interpolating the growth function as with the process-based model). In view of the above, the machine learning model as an alternative for the specific growth stages may perform consistent with the process-based model 116, for example, for the specific growth stages, in one or more embodiments, but may include the option to retain the model more readily based on addition and/or alternative and/or new data upon which the model relies, while also providing for cross-validation between the different models (for the same general growth stages).

Finally, in this example embodiment, the computing device 102 is configured to employ the dry down model 118 to determine the growth stages from R8 to harvest (H). In particular, the computing device 102 is configured to employ Equation 8, below, to determine the daily loss of moisture in the crop, where T_mean is the daily mean of the maximum and minimum temperatures in degrees Celsius, and Min_DDR is 4.4%. In this particular example, the daily loss is scaled by −0.5 when the field 106, for example, received more than about 1 inch of precipitation, and is set to zero for more than about 0.5 inches of precipitation but less than about 1 inch of precipitation. Daily loss is integrated starting with about 35% moisture at growth stage R8.

daily_loss=max(0.861*T_mean−1.448929, Min_DDR) (8)

Following the above, the computing device 102 is then configured to merge the outputs of the different models to provide the growth stages of the crop of the field 106, for example. In particular, for example, the prediction of the maturity model 114 of the R7 growth stage is considered herein to be preferred to the prediction of the process-based model 116. As such, the prediction of R1-R7 is scaled to align the process-based model prediction for R7 with the maturity model prediction, based on Equation 9, below.

$${days}_{R 1 - R n , f} = {days}_{R 1 - R n , i} * \frac{{days}_{R 1 - R 7 , f}}{{days}_{R 1 - R 7 , i}} \qquad ( 9 )$$

In Equation 9, days_{R1-Rn, f} is the final number of days between R1 and Rn; days__{R1-Rn,1} is the number of days between R1 and Rn predicted by the process-based model 116; days__{R1 R7}, f is the number of days between R1 and R7 predicted by the maturity model 114; and days__{R1-R7}, is the number of days between R1 and R7 predicted by the process-based model 116. It should be appreciated then that the number of days calculated in Equation 9 is added to the predicted R1 to derive the predicted Rn date.

It should be appreciated that as presented in the description above, the computing device 102 is configured to determine the growth stages of soybeans in the field 106, for example, whereby, in this example, the models are specific to soybeans in parameters, terms, etc. As such, other models, terms and parameters may be used for other crops (e.g., corn, etc.), along with more or less terms in certain of the models, to determine, or more generally, predict, the growth stages of a crop in the field 106 or other fields.

In particular, for example, the same or similar model training may be utilized in connection with determining growth stages of corn. For instance, the growing degree model 112, the maturity model 114 (and application of the null stage and weather-based stage) (and the alternative machine learning flowering model), and the process-based model 116 may be similarly implemented for corn. However, in implementing these models with regard to corn, different dates may be used (e.g., a planting date in place of an emergence date, etc.) as null features, different and/or additional weather features may be used, and/or different growth stage intervals may be applied based on the different growth stages, etc. (as illustrated, for example, in Table 2, which includes the growth stages for corn, versus Table 1, which includes the growth stages for soybeans; etc.) For instance, with regard to the different growth stage intervals for corn, the machine learning flowering model may use the intervals P-M and M-P50, where P is a planting date, P50 is a flowering date predicted by the null model, and M is a midpoint between the two. Similarly, the maturity model 114 uses the intervals P-P50 and P50-R6, where P is a planting date, P50 is a flowering date predicted by the model, and R6 is the R6 date predicted by the null model.

In addition, with regard to corn, the computing device 102 may be configured with a different model to predict dry down for corn, where the daily dry down rate may depend on the difference in the current moisture and the equilibrium moisture, and thus, not just the current moisture. In such an example, the following Equation 10 may be employed as a dry-down model for corn:

Mᵢ₊₁=−k_{M}(Mᵢ−M_{e,i})*vpdᵢ (10)

In Equation 10, Mᵢ is the moisture on day i, Mᵢ₊₁ is the moisture on day i+1, M_{e,i} is the equilibrium moisture on day i, k_{M} is a proportionality constant, and vpdᵢ is the vapor pressure deficient on day i, which combines the effects of temperature and humidity. Starting from an initial moisture on day i, then, Equation 10 integrates the equilibrium moisture to get a trajectory and to optimize k_{M}, and to minimize (M_{obs}−M_{pred})(excluding the first data point). M_{obs} and M_{pred} are the observed moisture and the predicted moisture, respectively. The model may then be used to provide a daily time series of moisture after the R6 growth stage of corn. The moisture model is used, in turn, to predict a “harvest-ready” date (which is, for example, H in Table 2) for a given moisture threshold, such as, for example, where moisture is 25% and the grain is ready to be harvested.

It should, of course, be appreciated that other dry down models (and other models, in general) may be employed for soybean, corn, or other types of crops in predicting growth stages.

Beyond the above, it should be appreciated that the computing device 102 may be further configured to provide post-processing with regard to such predictions for corn, whereby the computing device 102 is configured to interpolate stages other than P50 and R6 between the three points (i.e., planting date, P50 and R6) in a fashion similar to the R2-R6 stages for soybean. And, the computing device 102 may be configured to interpolate growth stages VE to VT, by a fractional progress of GDU, from the planting to predict P50, and to interpolate growth stages R2-R5, by the fractional progress of GDU, from the predicted P50 to the predicted R6.

In this example embodiment, from the above, the computing device 102 is configured to further leverage the growth stage prediction of the crop to operations associated with the crop and/or the field 106. For example, the computing device 102 may be configured to guide field operations (e.g., treatments (e.g., timing/amount/rate of fertilizers, herbicides, pesticides, or timing of UAV image capture (e.g., for canopy cover imaging, etc.) etc.), etc.) (e.g., as part of treatment instructions, treatment plans, etc. to treat the crop in the field 106 by the agricultural machine 108; etc.), or to define a harvest time (or harvest plan or harvest instructions) for the crop in the field 106 (e.g., for directing and/or routing harvesting operations, etc. of agricultural machines (e.g., combines, pickers, sprayers, etc.) (broadly, agricultural machine 108) to or within the field 106, etc.).

In other examples, the computing device 102 may be configured to compute yield predictions (e.g., amounts, times, etc.) based on the growth stages, and, potentially, measurements from the field 106, or scans and/or images of the field 106 or a combination thereof, which may, in turn, be used for product placement, performance assessment, etc. The predicted growth stages may further be used in combination with weather data to estimate drought conditions and disease susceptibility and/or with environmental prediction models that are growth-stage dependent; to aggregate environmental data for environment scenarios, which reflect the environmental conditions in which a crop is expected to perform well; and also provide a basis for detasseling and chemical spray planning for different crops (e.g., corn seed production, etc.). Beyond the above, it should be appreciated that the potential uses of the growth stages, especially, accurately predicted growth stages in advance of the specific growth stage may be used in various other implementations whereby the crop is understood, improved, etc., consistent with appropriate requirements, goals, or desired for the crop and/or the field(s) including the crops, etc.

From the above, based on the growth stage prediction of the crop in the field 106, for instance, the computing device 102 may generate one or more instructions (e.g., scripts, plans, etc.) for treating the crop, processing the crop, etc. based on the prediction. And, the computing device 102 may then transmit the instructions to the agricultural machine 108 whereby upon receipt, the agricultural machine 108 operates, in response to the instructions, to treat, process, etc. the crop in the field 106. Such treatment, processing, etc. of the crop, as defined by the instructions, may include applying one or more fertilizers, herbicides, pesticides, etc. (e.g., as part of a treatment plan, etc.); capturing data about the crops (e.g., images, etc.); harvesting part or all of the crop at a particular time (or at particular different times) according to a corresponding plan; harvesting part or all of the crop according to a particular harvesting route through the crop (e.g., based on growth stage(s) of crop(s) within the field 106, etc.) (e.g., as part of a corresponding harvest plan, etc.); etc.

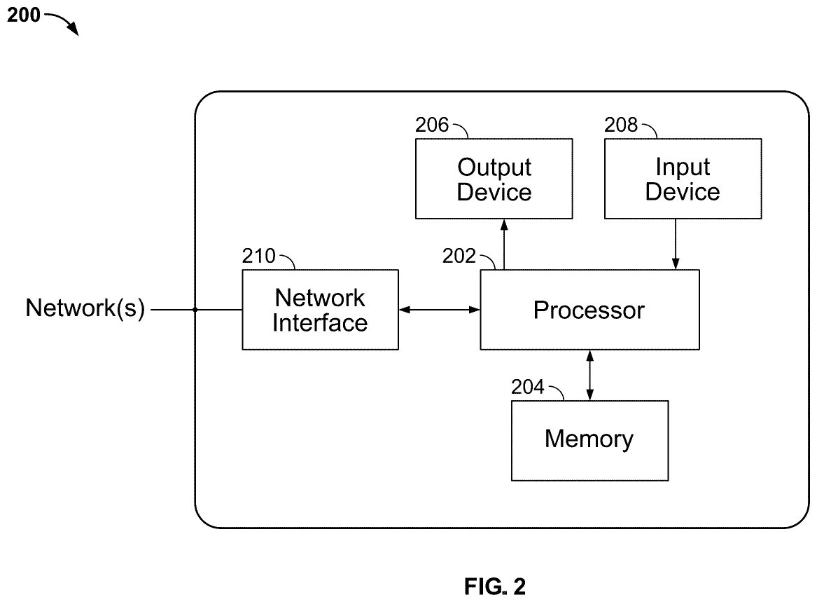

FIG. 2 illustrates an example computing device 200 that may be used in the system 100 of FIG. 1. The computing device 200 may include, for example, one or more servers, workstations, personal computers, laptops, tablets, smartphones, virtual devices, etc. In addition, the computing device 200 may include a single computing device, or it may include multiple computing devices located in close proximity or distributed over a geographic region, so long as the computing devices are specifically configured to operate as described herein. In the example embodiment of FIG. 1, the computing device 102 includes and/or is implemented in one or more computing devices consistent with computing device 200. The database 104 and the agricultural machine 108 may also be understood to include and/or be implemented in one or more computing devices, at least partially consistent with the computing device 200. However, the system 100 should not be considered to be limited to the computing device 200, as described below, as different computing devices and/or arrangements of computing devices may be used. In addition, different components and/or arrangements of components may be used in other computing devices.

As shown in FIG. 2, the example computing device 200 includes a processor 202 and a memory 204 coupled to (and in communication with) the processor 202. The processor 202 may include one or more processing units (e.g., in a multi-core configuration, etc.). For example, the processor 202 may include, without limitation, a central processing unit (CPU), a microcontroller, a reduced instruction set computer (RISC) processor, a graphics processing unit (GPU), an application specific integrated circuit (ASIC), a programmable logic device (PLD), a gate array, and/or any other circuit or processor capable of the functions described herein.

The memory 204, as described herein, is one or more devices that permit data, instructions, etc., to be stored therein and retrieved therefrom. In connection therewith, the memory 204 may include one or more computer-readable storage media, such as, without limitation, dynamic random access memory (DRAM), static random access memory (SRAM), read only memory (ROM), erasable programmable read only memory (EPROM), solid state devices, flash drives, CD-ROMs, thumb drives, floppy disks, tapes, hard disks, and/or any other type of volatile or nonvolatile physical or tangible computer-readable media for storing such data, instructions, etc. In particular herein, the memory 204 is configured to store data including, without limitation, models, weather data, field data, planning data, and/or other types of data (and/or data structures) suitable for use as described herein.

Furthermore, in various embodiments, computer-executable instructions may be stored in the memory 204 for execution by the processor 202 to cause the processor 202 to perform one or more of the operations described herein (e.g., one or more of the operations of method 300, etc.) in connection with the various different parts of the system 100, such that the memory 204 is a physical, tangible, and non-transitory computer readable storage media. Such instructions often improve the efficiencies and/or performance of the processor 202 that is performing one or more of the various operations herein, whereby such performance may transform the computing device 200 into a special-purpose computing device. It should be appreciated that the memory 204 may include a variety of different memories, each implemented in connection with one or more of the functions or processes described herein.

In the example embodiment, the computing device 200 also includes an output device 206 that is coupled to (and is in communication with) the processor 202 (e.g., a presentation unit, etc.). The output device 206 may output information (e.g., growth stage data, etc.), visually or otherwise, to a user of the computing device 200, such as a researcher, grower, technician, etc. It should be further appreciated that various interfaces (e.g., as defined by network-based applications, websites, etc.) may be displayed or otherwise output at computing device 200, and in particular at output device 206, to display, present, etc. certain information to the user. The output device 206 may include, without limitation, a liquid crystal display (LCD), a light-emitting diode (LED) display, an organic LED (OLED) display, an “electronic ink” display, speakers, a printer, etc. In some embodiments, the output device 206 may include multiple devices. Additionally or alternatively, the output device 206 may include printing capability, enabling the computing device 200 to print text, images, and the like on paper and/or other similar media.

In addition, the computing device 200 includes an input device 208 that receives inputs from the user (i.e., user inputs) such as, for example, selections of crops, etc. The input device 208 may include a single input device or multiple input devices. The input device 208 is coupled to (and is in communication with) the processor 202 and may include, for example, one or more of a keyboard, a pointing device, a touch sensitive panel, or other suitable user input devices. It should be appreciated that in at least one embodiment the input device 208 may be integrated and/or included with the output device 206 (e.g., a touchscreen display, etc.).

Further, the illustrated computing device 200 also includes a network interface 210 coupled to (and in communication with) the processor 202 and the memory 204. The network interface 210 may include, without limitation, a wired network adapter, a wireless network adapter, a mobile network adapter, or other device capable of communicating to one or more different networks (e.g., one or more of a local area network (LAN), a wide area network (WAN) (e.g., the Internet, etc.), a mobile network, a virtual network, and/or another suitable public and/or private network, etc.), including suitable networks capable of supporting wired and/or wireless communication between the computing device 200 and other computing devices, including with other computing devices used as described herein (e.g., between the computing device 102, the database 104, etc.).

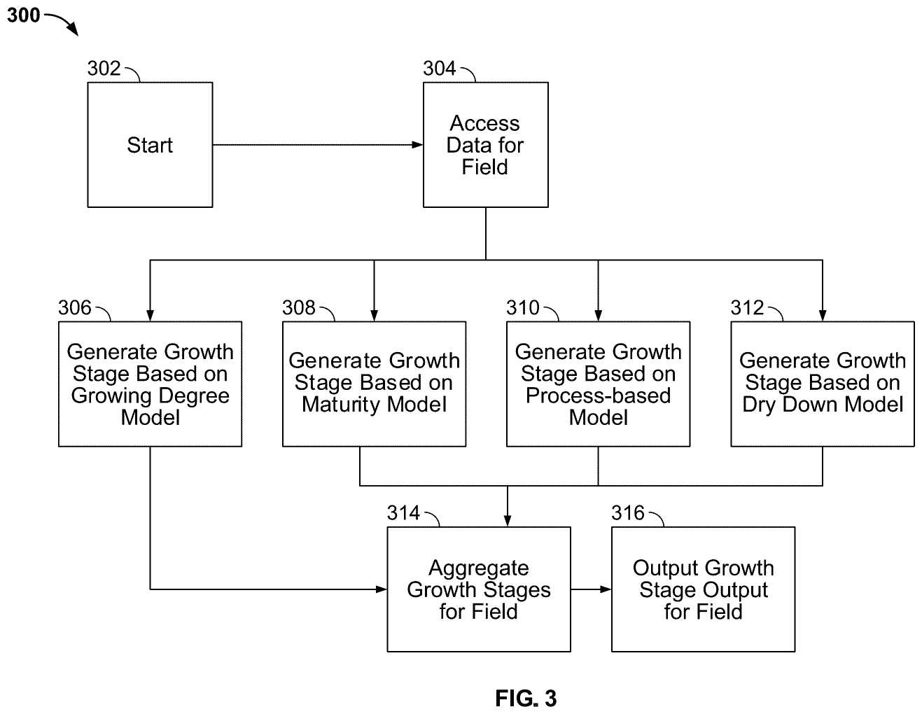

FIG. 3 illustrates an example method 300 for predicting growth stages of a crop in a field. The example method 300 is described herein in connection with the system 100, and may be implemented, in whole or in part, in the computing device 102 of the system 100. Further, for purposes of illustration, the example method 300 is also described with reference to the computing device 200 of FIG. 2. However, it should be appreciated that the method 300, or other methods described herein, are not limited to the system 100 or the computing device 200. And, conversely, the systems, data structures, and the computing devices described herein are not limited to the example method 300.

At the outset, it should be appreciated that the method 300 is directed, in the description below, to the field 106 in the system 100. However, the method 300 may be applied to additional, or different fields, or parts thereof, plots thereof, etc., in other embodiments.

Initially, at 302, the computing device 102 initiates the method by executing one or more schedules to determine growth stages, per field, or for groups of fields, etc. The schedule may include, for example, a regular or irregular interval, such as, for example, daily, weekly, or monthly, etc. In one specific example, the computing device 102 initiates method 300 multiple times per week, such as, for example, three time per week. That said, it should be appreciated that the method 300 may be executed whenever required or desired. In various embodiments, the computing device 102 initiates the method to determine the growth stages for a particular field, or group of fields, in response to an input from a grower, breeder of the crop planted in the field(s), or other user associated with the field(s).

At 304, the computing device 102 (e.g., processor 202 thereof, etc.) accesses relevant data for the field 106 from the database 104. The relevant data may include, for example, crop data (e.g., planting date, crop type, etc.), weather data (e.g., temperature, humidity, etc.), data associated with sunrise and sunset (e.g., indicative of length of day, or photoperiods, etc.), management data (e.g., irrigation, etc.) and for some regions, soil data (e.g., available water capacity, etc.). etc. The computing device 102 also accesses the models associated with the specific field 106 (e.g., based on region, type of crop in the field 106, etc.), and associated parameters (e.g., resulting from prior training of the model(s), etc.), etc., from memory therein (e.g., from memory 204 thereof, etc.), or from the database 104, etc. In this example embodiment, the models include the growing degree model 112, the maturity model 114, the process-based model 116, and the dry down model 118 (for soybeans as the crop planted in the field 106).

The computing device 102 then computes, or generates, the growth stage data, based on the accessed models, for the specific range(s) of growth stages associated with the models. It should be appreciated that despite the particular illustration of execution of the models in FIG. 3, the different models may be executed in parallel, in series, or in some combination thereof.

In this example embodiment, at 306, the computing device 102 determines the growth stages, from planting (P) to V8 and from R7 to R8 based on the growing degree model 112, for example, as presented in Equations 1-3, above. As such, the growth stages are based on temperature of the field 106, at specific intervals (e.g., a mean temperature from 14 days before planting up to a desired date, etc.), and also the relative maturity (RM), which is defined, for example, by the supplier, or breeders responsible for the line/seed of the crop, etc. The computing device 102, accordingly, determines the GDU, or growing degree units, for each of the different growth stage ranges, for example, from planting (P) to emergence (E), from V1 to V8, and from R7 to R8.

At 308, the computing device 102 determines the growth stages, from emergence (E) to R7, based on the maturity model 114, for example, as presented above. In particular, the computing device 102 predicts the growth stage data in a two-stage process, through a null stage and a weather-based stage. In one example, the null stage may include the expression of the planting/emergence day, RM and latitude, and pairwise combinations of these parameters, thereby providing six null features. In another example, the null stage may include the expression of the planting/emergence day, latitude, longitude, RM, elevation, and irrigation (e.g., expressed as True/False, etc.), thereby again providing six null features (but without (or independent of) pairwise combinations or interaction features, etc.). The weather-based stage includes the aggregation (e.g., average, sum, other aggregation, etc.) of weather data over the first half of the growing period (or growth stages) and separately over the second half of the growing period (or growth stages), as defined by a rough midpoint, e.g., emergence to midpoint and midpoint to R7, etc.

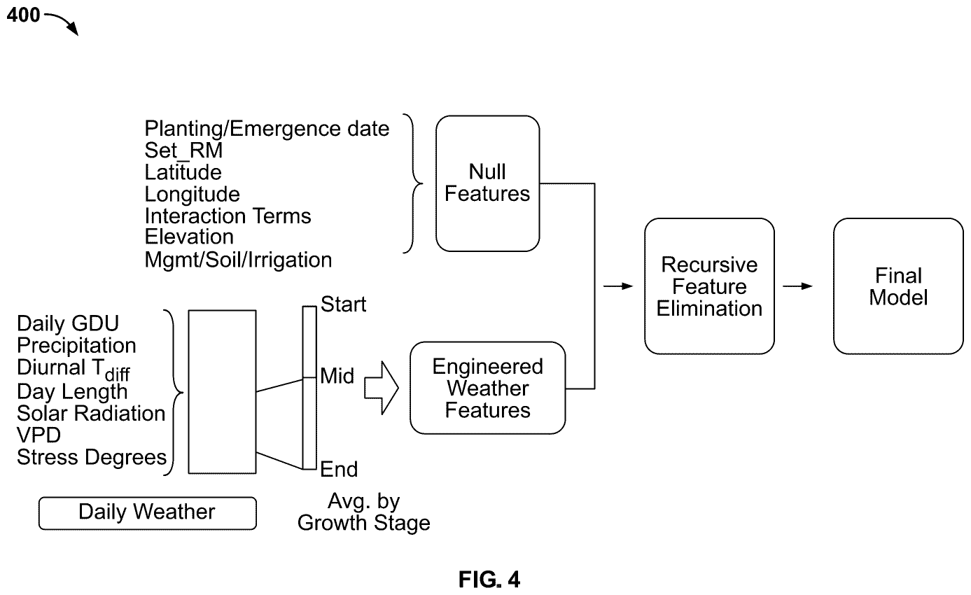

With additional reference to the flow 400 in FIG. 4, the maturity model 114, in this embodiment, generally relies on location, weather and genetic features of the crop in the field 106, where a machine learning model (e.g., a linear regression model, a Gaussian process regression model, etc.) is employed to predict the growth stage from E to R7, via a null stage/model and a weather-based stage/model.

As shown in FIG. 4, in the null stage, the computing device 102 compiles different null features of the crop, based on planting/emergence day/date, set relative maturity (RM), latitude, longitude, elevation, management/soil/irrigation, and/or combinations and/or interactions thereof. As generally described above, the combinations (when employed) may include, for example, set_RM*emergence_day, set_RM*latitude, and emergence_day*latitude. In general, then, the computing device 102 compiles six null features of the crop(s) in this example embodiment. It should be appreciated, again, that the features noted above may be employed individually, or in combination, depending on the particular model, and capabilities and/or configurations thereof. For instance, a linear regression model may employ multiple features in combination (as indicated above), while a Gaussian process regression model may employ individual ones of the features.

The weather-based stage, then, includes weather features aggregated (e.g., averaged, etc.) over two parts of the growth stage. The two parts may include emergence to a midpoint, for example, and then from the midpoint to roughly R7, where the weather features include in this example, without limitation, daily GDU, precipitation, diurnal temperature difference per day (or other interval) (i.e., Tₘₐₓ−Tₘᵢₙ), day length, and solar radiation, VPD, stress degrees (e.g., degree days over 30° C. or other temperature threshold, etc.), etc. The computing device 102, as part of the maturity model 114, then combines the weather features and the null features from the two stages.

In turn, following the combination, in some example embodiments, the computing device 102 then employ a backwards recursive elimination process, whereby the set of the null and weather features is reduced to an optimal set. Specifically, for example, if the null and weather features provide N features, the computing device 102 is configured to try feature elimination for each and to assess the impact of the individual feature elimination on performance of the model 114. The feature elimination which least impacts the performance of the model 114 is identified, and is then repeated until a limited set of the features is returned, which is within a threshold (e.g., 1%, 2%, 5%, or more or less, etc.), for example, of the root mean square error of the optimal final model. As discussed above, though, it should be appreciated that the backwards recursive feature elimination is not required in all embodiments and/or implementations of the flow 400.

Referring back to FIG. 3, at 310, the computing device 102 determines the growth stages, from emergence (E) to R1 and from R1 to R7, based on the process-based model 116, for example, as presented in Equations 4-7, above, or alternatively based on the machine learning model for VE to R1 and R1 to R7 (as described above), whereby the output includes the predicted dates for R1, R2, etc.

And, at 312, the computing device 102 determines the growth stages, from R8 to harvest (H), based on the dry down model 118, for example, as presented in Equation 8, above. For example, the dry down model 118 provides a predicted daily loss of moisture, which begins at the date of the R8 growth stage, starting, for example, at 35% moisture on that date, whereby a harvest date is predicted at the 25% moisture date. Other moisture thresholds, of course, may be relied upon in other embodiments.

After, the computing device 102 aggregates, at 314, the growth stages from the different models, for the field 106, to define a specific growth stage output for the field 106 (e.g., for the particular crop in the field 106, etc.).

In this example embodiment, as noted above, the R7 growth stage is predicted based on each of the growing degree model 112, the maturity model 114 and the process-based model 116. As such, the dates are used to align the different predictions. Specifically, in this example, the maturity model 114, for example, may be identified as more accurate (as compared to the growing degree model 112 and the process-based model 116), whereby the predicted day of the R7 growth stage from each of the growing degree model 112 and the process-based model 116 is adjusted to coincide with the day of the R7 growth stage predicted by the maturity mode 114, and other days of the R7-R8 predictions from the growing degree model 112 as well as the process-based prediction are adjusted accordingly. With regard to the process-based model 116, this is accomplished by use of Equation 9, above. In this manner, the process-based model 116 is leveraged to predict the growth stages from V1 to R7, yet subject to the prediction of the maturity model 114. It should be appreciated that the models may otherwise be associated and/or adjust to account for the accuracy of the specific models at similar or the same growth stages, and to facilitate cooperation among the predictions of the models.

Finally, at 316, the computing device 102 outputs the growth stage output to one or more associated processes. For example, the growth stage output may be used to define operations of the field (e.g., treatments, testing, imaging, etc.), or make predictions about yield or harvest timing, etc. For instance, based on the growth stage output, the computing device 102 may generate one or more instructions (e.g., scripts, etc.) for treating the crop, processing the crop, etc. based on the prediction. And, the computing device 102 may then transmit the instructions to the agricultural machine 108 whereby upon receipt, the agricultural machine 108 operates, in response to the instructions, to treat, process, etc. the crop in the field 106. Such treatment, processing, etc. of the crop, as defined by the instructions, may include applying one or more fertilizers, herbicides, pesticides, etc. (e.g., as part of a treatment plan for the crop in the field 106, etc.); capturing date about the crops (e.g., images, etc.); harvesting part or all of the crop at a particular time (or at particular different times); harvesting part or all of the crop according to a particular harvesting route through the crop (e.g., based on growth stage(s) of crop(s) within the field 106, etc.) (e.g., as part of a harvest plan for the crop in the field 106, etc.); etc.

As described above, in some implementations of the system 100 and the method 300, the maturity model 114 and/or process-based model 116 may be omitted in favor of a further machine learning model, for example, a machine learning flowering model. In one specific embodiment, for example, the machine learning flowering model may include a regression model for growth stages VE to R1 and R1 to R7, where the regression model incorporates location, weather and genetic features. In connection therewith, the machine learning flowering model is generally consistent with the above in training for null and weather-based modeling and in including a recursive elimination of features and estimates of the model error through a leave-one-year-out cross validation.

In some implementations of the method 300 (and system 100), a post-processing operation may optionally be employed following aggregation of the growth stages (e.g., in the method 300 between operations 314 and 316, etc.) (e.g., in general, or as a fifth or further model, etc.). In doing so, computing device 102 receives in-season images (e.g., satellite images, UAV images, etc.) of the field 106, whereby the computing device 102 employs one or more models to determine the growth stage of the crops in the fields 106 (e.g., based on color bands, NVDI, etc.), and based thereon, to verify (or validate) the growth stage output from the models (e.g., as part of providing in-season feedback to the above network 110, etc.). In turn, one or more of the models of the network 110 may be updated, the aggregation of the output of the of the growth stages may be updated, as needed, and/or one or more warnings may be provided. The updates and/or warning are, then, based on one or more differences between the predicted growth stage output from the above model(s) and the growth stage(s) as indicated in the images.

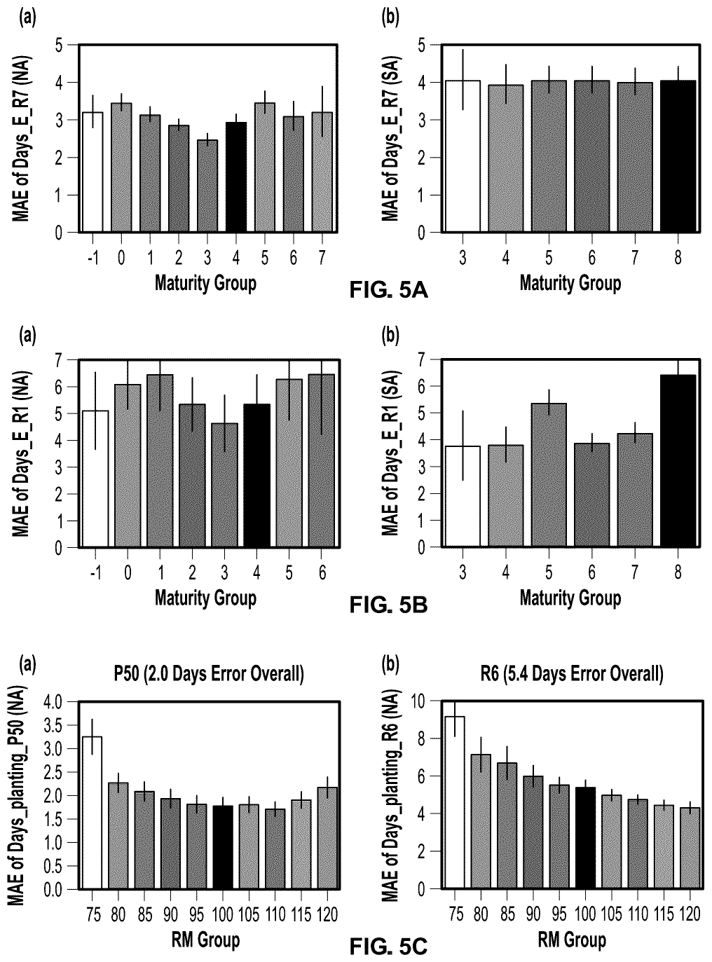

That said, FIGS. 5A-5B illustrate graphical representations of performance of the maturity model 114 and the machine learning flowering model in North America (NA) and South America (SA) for soybeans (e.g., for different maturity groups, etc.). For instance, FIG. 5A illustrates, in chart (a), cross-year mean absolute error (MAE) of the maturity model 114 in North America for soybeans, from leave-one-year-out cross-validation (LOYO) over 2016-2021, averaged by relative maturity group. And, chart (b) of FIG. 5A illustrates cross-year mean absolute error of the maturity model 114 in South America for soybeans, from LOYO over 2015-2020 crop years, averaged by relative maturity group. FIG. 5B then illustrates, in chart (a), cross-year mean absolute error of the machine learning flowering model in North America for soybeans, from LOYO over 2016-2021, averaged by relative maturity group. And, chart (b) of FIG. 5B illustrates cross-year mean absolute error of the machine learning flowering model in South America for soybeans, from LOYO over 2015-2020, averaged by relative maturity group.

Further, FIG. 5C illustrates graphical representations of performance of the maturity model 114 and the machine learning flowering model in North America (NA) for corn (e.g., for different maturity groups, etc.). Further, for instance, FIG. 5C illustrates, in chart (a), cross-year mean absolute error of the machine learning flowering model, from leave-one-year-out cross-validation (LOYO) over 2016-2020, averaged by relative maturity group. And, chart (b) of FIG. 5C illustrates cross-year mean absolute error of the maturity model 114, from LOYO over 2016-2020 crop years, averaged by relative maturity group. That said, it should be appreciated that one or more maturity models for NA for corn may generally include different target variables (e.g., GDU planting-R6 versus days emergence-R7, etc.) and/or different features (e.g., planting date versus emergence date, etc.), as compared to soy maturity model(s).

In view of the above, the systems and methods herein may provide for leveraging multiple different models to accurately predict the growth stages of crops in fields (e.g., soybean crops, corn crops, etc.) (broadly, predict phenotypes of the crops), after planting, and in the midst of (or during) the growing period of the crops in the fields. What's more, the systems and methods herein are applicable for providing predictions across multiple global regions (e.g., across both North America and South America, etc.) via the same models and/or combination of models (e.g., where previously different models were required for different regions, etc.).

With that said, it should be appreciated that the functions described herein, in some embodiments, may be described in computer executable instructions stored on a computer readable media, and executable by one or more processors. The computer readable media is a non-transitory computer readable media. By way of example, and not limitation, such computer readable media can include RAM, ROM, EEPROM, CD-ROM or other optical disk storage, magnetic disk storage or other magnetic storage device, or any other medium that can be used to carry or store desired program code in the form of instructions or data structures and that can be accessed by a computer. Combinations of the above should also be included within the scope of computer-readable media.

It should also be appreciated that one or more aspects of the present disclosure may transform a general-purpose computing device into a special-purpose computing device when configured to perform one or more of the functions, methods, and/or processes described herein.

As will be appreciated based on the foregoing specification, the above-described embodiments of the disclosure may be implemented using computer programming or engineering techniques, including computer software, firmware, hardware or any combination or subset thereof, wherein the technical effect may be achieved by performing at least one of the following operations: (a) accessing data associated with a target field and/or a crop in the target field; (b) generating growth stage predictions, via multiple growth stage models, each associated with an interval of a growth period of the crop; (c) aggregating the growth stage predictions from the multiple growth stage models; (d) outputting the aggregate growth stage prediction for the field; and (e) instructing, by the computing device, operation of an agricultural machine relative to the target field and/or the crop in the target field based on the aggregate growth stage prediction for the field.

Examples and embodiments are provided so that this disclosure will be thorough, and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail. In addition, advantages and improvements that may be achieved with one or more example embodiments disclosed herein may provide all or none of the above-mentioned advantages and improvements and still fall within the scope of the present disclosure.

Specific values disclosed herein are example in nature and do not limit the scope of the present disclosure. The disclosure herein of particular values and particular ranges of values for given parameters are not exclusive of other values and ranges of values that may be useful in one or more of the examples disclosed herein. Moreover, it is envisioned that any two particular values for a specific parameter stated herein may define the endpoints of a range of values that may also be suitable for the given parameter (i.e., the disclosure of a first value and a second value for a given parameter can be interpreted as disclosing that any value between the first and second values could also be employed for the given parameter). For example, if Parameter X is exemplified herein to have value A and also exemplified to have value Z, it is envisioned that parameter X may have a range of values from about A to about Z. Similarly, it is envisioned that disclosure of two or more ranges of values for a parameter (whether such ranges are nested, overlapping or distinct) subsume all possible combination of ranges for the value that might be claimed using endpoints of the disclosed ranges. For example, if parameter X is exemplified herein to have values in the range of 1-10, or 2-9, or 3-8, it is also envisioned that Parameter X may have other ranges of values including 1-9, 1-8, 1-3, 1-2, 2-10, 2-8, 2-3, 3-10, and 3-9.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When a feature is referred to as being “on,” “engaged to,” “connected to,” “coupled to,” “associated with,” “in communication with,” or “included with” another element or layer, it may be directly on, engaged, connected or coupled to, or associated or in communication or included with the other feature, or intervening features may be present. As used herein, the term “and/or” and the phrase “at least one of” includes any and all combinations of one or more of the associated listed items.

Although the terms first, second, third, etc. may be used herein to describe various features, these features should not be limited by these terms. These terms may be only used to distinguish one feature from another. Terms such as “first,” “second,” and other numerical terms when used herein do not imply a sequence or order unless clearly indicated by the context. Thus, a first feature discussed herein could be termed a second feature without departing from the teachings of the example embodiments.

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

What is claimed is:

1. A computer-implemented method for use in predicting growth stages of crops in fields, the method comprising:
accessing, by a computing device, data associated with a target field and/or a crop in the target field;
generating, by the computing device, growth stage predictions, via multiple growth stage models, each associated with an interval of a growth period of the crop;
aggregating, by the computing device, the growth stage predictions from the multiple growth stage models; and
outputting, by the computing device, the aggregate growth stage prediction for the field.

2. The computer-implemented method of claim 1, wherein the data includes weather data for the target field; and
wherein the weather data includes humidity data and temperature data for the target field.

3. The computer-implemented method of claim 1, wherein the multiple models include a growing degree model specific to prediction of growth stages at least between planting and vegetation of the crop in the target field; and
wherein the growing degree model is based on, in part, relative maturity of the crop and a mean temperature over an interval.

4. The computer-implemented method of claim 1, wherein the multiple models include a machine learning model specific to prediction of growth stages between vegetation and beginning maturity (R7) of the crop; and
wherein the machine learning model is based on ones of: daily growing degree units (GDU), precipitation, diurnal temperature difference per day, day length, and/or stress degrees for the crop in the target field.

5. The computer-implemented method of claim 4, further comprising training the machine learning model through feature selection from among the GDU, the precipitation, the diurnal temperature difference per day, the day length, and/or the stress degrees for the crop in the target field;
wherein the feature selection is based on an estimated midpoint between vegetation and beginning maturity (R7).

6. The computer-implemented method of claim 1, wherein the multiple models include a machine learning model specific to prediction of growth stages between emergence and beginning maturity (R7).

7. The computer-implemented method of claim 1, wherein the multiple models include a processed-based model specific to prediction of growth stages between emergence and beginning maturity (R7), based on one or more of the following expression(s):
$$R\_max = f ( T ) * f ( P ) * f ( DP ) ;$$
$$f ( T ) = min ( \frac{G D U}{GDU\_max} , 1 ) ;$$
$$f ( P ) = \frac{1}{1 + {e}^{( {k}_{p} * {( P - {P}_{m i d} )}^{7}}} ; and / or$$
$$f ( DP ) = \{ \begin{matrix}1 if DP > 0 \\ 1 - \frac{D P}{DP\_max} if DP > DP\_max \\ 0 if DP \geq DP\_max\end{matrix} .$$

8. The computer-implemented method of claim 1, further comprising validating the machine learning model based on leave-one-interval-out data reserved from training the model; and
wherein the interval includes a year.

9. The computer-implemented method of claim 1, wherein the multiple models include a dry down model specific to prediction of growth stage between full maturity (R8) and harvest.

10. The computer-implemented method of claim 9, wherein the dry down model is specific to the crop in the field.

11. The computer-implemented method of claim 1, wherein outputting the aggregate growth stage prediction for the field includes displaying the growth stages to a user.

12. The computer-implemented method of claim 1, further comprising instructing, by the computing device, operation of an agricultural machine relative to the target field and/or the crop in the target field based on the aggregate growth stage prediction for the field.

13. The computer-implemented method of claim 12, wherein instructing the operation of the agricultural machine includes instructing the agricultural machine to treat the crop in the target field based on the aggregate growth stage prediction for the field and/or harvest the crop in the field based on the aggregate growth stage prediction for the field.

14. The computer-implemented method of claim 12, wherein instructing the operation of the agricultural machine includes generating a harvest plan for harvesting the crop in the field, based on the aggregate growth stage prediction for the field, and transmitting the harvest plan to the agricultural machine, whereby the agricultural machine operates to harvest the crop in the field in response to the harvest plan.

15. The computer-implemented method of claim 14, further comprising harvesting the crop in the field in accordance with the harvest plan.

16. The computer-implemented method of claim 12, wherein instructing the operation of the agricultural machine includes generating a treatment plan for treating the crop in the field, based on the aggregate growth stage prediction for the field, and transmitting the treatment plan to the agricultural machine, whereby the agricultural machine operates to treat the crop in the field in response to the treatment plan.

17. The computer-implemented method of claim 16, further comprising treating the crop in the field in accordance with the treatment plan.

18. A system for use in predicting growth stages of crops in fields, the system comprising at least one computing device configured to:
access data associated with a target field and/or a crop in the target field;
generate growth stage predictions, via multiple growth stage models, each associated with an interval of a growth period of the crop;
aggregate the growth stage predictions from the multiple growth stage models;
output the aggregate growth stage prediction for the field; and
generate instructions for an agricultural machine, based on the aggregate growth stage prediction for the field, to treat the crop in the field and/or to harvest the crop in the field, whereby the agricultural machine operates to treat and/or harvest the crop in the field in response to the instructions.

19. The system of claim 18, wherein the at least one computing device is further configured to transmit the generated instructions to the agricultural machine.

20. The system of claim 19, further comprising the agricultural machine;
wherein the agricultural machine includes at least one processor configured to execute the instructions received from the at least one computing device to cause the agricultural machine to treat and/or harvest the crop in the field in accordance with the instructions.

21. The system of claim 18, wherein the multiple models include a machine learning model specific to prediction of growth stages between vegetation and beginning maturity (R7) of the crop.

22. A non-transitory computer-readable storage medium including executable instructions for predicting growth stages of a crop in a field, which when executed by at least one processor, cause the at least one processor to:
access data associated with a target field and/or a crop in the target field;
generate growth stage predictions, via multiple growth stage models, each associated with an interval of a growth period of the crop;
aggregate the growth stage predictions from the multiple growth stage models; and
output the aggregate growth stage prediction for the field.

23. The non-transitory computer-readable storage medium of claim 22, wherein the multiple models include a machine learning model specific to prediction of growth stages between vegetation and beginning maturity (R7) of the crop; and
wherein the machine learning model is based on ones of: daily growing degree units (GDU), precipitation, diurnal temperature difference per day, day length, and/or stress degrees for the crop in the target field.

24. The non-transitory computer-readable storage medium of claim 23, wherein the executable instructions, when executed by the at least one processor, further cause the at least one processor to train the machine learning model through feature selection from among the GDU, the precipitation, the diurnal temperature difference per day, the day length, and/or the stress degrees for the crop in the target field;
wherein the feature selection is based on an estimated midpoint between vegetation and beginning maturity (R7).

25. The non-transitory computer-readable storage medium of claim 24, wherein the multiple models include a processed-based model specific to prediction of growth stages between emergence and beginning maturity (R7), based on one or more of the following expression(s):
$$R\_max = f ( T ) * f ( P ) * f ( DP ) ;$$
$$f ( T ) = min ( \frac{G D U}{GDU\_max} , 1 ) ;$$
$$f ( P ) = \frac{1}{1 + {e}^{( {k}_{p} * {( P - {P}_{m i d} )}^{7}}} ; and / or$$
$$f ( DP ) = \{ \begin{matrix}1 if DP > 0 \\ 1 - \frac{D P}{DP\_max} if DP > DP\_max \\ 0 if DP \geq DP\_max\end{matrix} .$$

26. The non-transitory computer-readable storage medium of claim 22, wherein the executable instructions, when executed by the at least one processor, further cause the at least one processor to instruct operation of an agricultural machine relative to the target field and/or the crop in the target field based on the aggregate growth stage prediction for the field.
